(19) United States
(12) Patent Application Publication
(10) Pub. No.: US 2016/0289062 A1
(43) Pub. Date: Oct. 6, 2016

(54) MEMS PACKAGING

(71) Applicant: QUALCOMM Technologies International, Ltd., Cambridge (GB)

(72) Inventor: Kevin CANNON, Cambridge (GB)

(21) Appl. No.: 14/675,214

(22) Filed: Mar. 31, 2015

(51) Int. Cl. B81B 7/00

(52) U.S. Cl. CPC B81B 7/0038

(57) ABSTRACT

A packaged electronic component comprising at least one movable part, comprising lower and upper layers, each formed with a depression in an inwards-facing side of the component, the depressions forming a cavity within the component, a MEMs component rigidly joined at least one proximal location to the lower and upper layers, wherein the MEMs component extends from the at least one proximal location into the cavity such that a distal region of the MEMs component can move within the cavity.

### BACKGROUND

MicroElectroMechanical (MEM) systems present opportunities for reducing the size of electronic devices. It is possible to construct mechanical devices many times smaller than conventional components.

A particularly interesting type of MEMs device is an energy harvester. Here a movable component converts motion into electrical energy to power an electronic device with which the harvester is associated. Self-powered devices may thus be possible.

The deployment of MEMs devices in commercial products requires both that the devices provide the required function, and that suitable packaging techniques exist to package the devices in a robust and commercially appropriate manner.

Packaging of MEMs devices can be complex due to the requirement to house moving components which require open spaces within a packaged component.

The embodiments described below are not limited to implementations which solve any or all of the disadvantages of known arrangements for packaging MEMs devices.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

There is provided a packaged electronic component comprising at least one movable part, comprising lower and upper layers, each formed with a depression in an inwards-facing side of the component, the depressions forming a cavity within the component, a MEMs component rigidly joined at least one proximal location to the lower and upper layers, wherein the MEMs component extends from the at least one proximal location into the cavity such that a distal region of the MEMs component can move within the cavity.

The packaged electronic component may further comprise a spacer layer between the lower and upper layers.

The packaged electronic component may further comprise a redistribution layer on the outer face of the lower or upper layer.

The packaged electronic component may further comprise at least one electrical via connecting the MEMs component to at least one redistribution layer.

The packaged electronic component may further comprise a redistribution layer on the outer face of the lower and upper layers, and at least one electrical via between those redistribution layers.

The MEMs component may be an elongate device rigidly joined at one location.

The MEMs component may be a planar device rigidly joined at a plurality of locations.

The MEMs component may act as an energy harverster.

The MEMs component may operate according to the triboelectric effect.

The packaged electronic component may further comprise magnetic material on the MEMs component to form a bistable device.

The upper and lower layers may be formed of glass, and the spacer layer is formed of Silicon.

The MEMs component and spacer layer may be formed of the same material.

The upper and lower layers may each be formed of a layer of glass with through-holes and a layer of Silicon covering one side of at least one of the through-holes to form the respective depression.

The packaged electronic component may further comprise a getter in the cavity.

The cavity may be filled with an inert gas.

The cavity may be filled with a reduced pressure atmosphere.

The preferred features may be combined as appropriate, as would be apparent to a skilled person, and may be combined with any of the aspects of the invention.

### BRIEF DESCRIPTION OF THE DRAWINGS

Embodiments of the invention will be described, by way of example, with reference to the following drawings, in which:

FIG. 1 shows a cross section through a packaged MEMs device; and

FIGS. 2A and 2B shows plan and cross section views of a packaged MEMs device.

### DETAILED DESCRIPTION

Embodiments of the present invention are described below by way of example only. These examples represent the best ways of putting the invention into practice that are currently known to the Applicant although they are not the only ways in which this could be achieved. The description sets forth the functions of the example and the sequence of steps for constructing and operating the example. However, the same or equivalent functions and sequences may be accomplished by different examples.

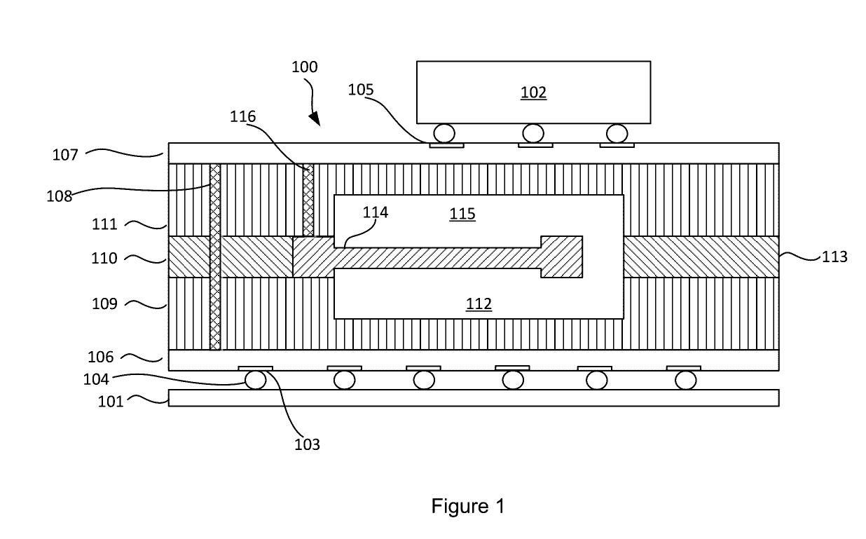

FIG. 1 shows a cross-section of a packaged MEMs energy harvester device 100. In particular the package 100 forms an interposer structure between a circuit board 101 and other electronic components 102. Such an arrangement allows the device to act as a redistribution and mounting layer for electronic components 102. The underside of the package 100 is provided with solder pads 103 for electrically connecting the package to a circuit board 101 on which the device 100 is mounted, for example using solder balls 104. The circuit board 101 may be a flexible structure, making the assembly particularly attractive for use in wearable devices.

The upper side of the package 100 may be provided with further solder pads 105 for the mounting electronic components 102. The connection between electronic components 102 and the device 100, and the device 100 and circuit board 101 may be provided utilising any appropriate method.

Solder pads 103, 105 are formed as part of redistribution layers 106, 107 comprising electrically conductive tracks. Tracks on the upper and under sides may be connected by conductive vias 108 formed through the device as explained below.

The package 100 comprises 3 layers 109, 110, 111 of material. Lower layer 109 is formed with a depression 112 in its upper surface. Middle layer 110 comprises a spacer layer 113 and MEMs component 114. Spacer layer 113 is formed to extend around depression 112 and to be of the same thickness as MEMs component 114. Upper layer 111 is formed with a depression 115 in its lower surface, corresponding to depression 112 in lower layer 109.

The lower and upper layers may be formed of a glass material and the spacer layer is formed of the same material as the MEMs component, for example Silicon. In alternative examples the spacer layer may be formed of a different material to the MEMs component, but that material should have comparable mechanical characteristics and be appropriate for bonding to the upper and lower layers. Furthermore, the spacer layer and MEMs component may be formed as a single piece.

The depressions 112,115 may be formed using an etching technique such as acidic etching. However, with such etch techniques it can be difficult to achieve a smooth and planar depression and typically an irregular cavity is achieved due to process difficulties. Such methods typically have reduced cost and may be appropriate where the cavity does not need to be well defined, for example, where there is minimal movement of the MEMs component.

In an alternative technique the upper and lower layers 109,111 may each be formed of two layers. A first layer may be formed with a through-hole in the area of the depression, and then an outer layer is bonded over that hole such that a single layer with a depression is formed. The layer with the through-hole may be formed of glass and the outer layer of silicon. Such an arrangement leads to alternating layers of Silicon and glass giving good potential for anodic bonding of the component.

MEMs component 114 is fixed at its proximal end between the lower layer 109 and upper layer 111. The MEMs component 115 is elongate and is formed of a flexible material such that by flexing of the component 114 the distal end can move up and down in the plane of the paper in FIG. 1. Lower layer 106, spacer layer 113 and upper layer 111 together form a package with a cavity 112, 115 in which distal end of the MEMs component 114 can move. Vias 116 provide electrical connections between the MEMs component and the redistribution layer 107. In the example connection is made to later 107, but it will be apparent that connections can also, or instead, be made to layer 106.

The MEMs component 114 may provide a variety of functions, for example the component may be an accelerometer or energy harvester. The component is provided with elements which generate an electrical current or voltage in response to movement of the distal end of the component. For example, the component may be provided with Piezo elements which convert movement to electricity. In the case of an accelerometer the electrical signals may be processed to determine movement of the device, or in the case of an energy harvester the signals may be utilised to power, directly or indirectly, the system in which the package is utilised.

During manufacture the components of the package are assembled and bonded together using an appropriate manufacturing technique. The layers may be anodic or fusion bonded together, or another bonding method may be utilised as appropriate for the materials.

Holes to form vias 105, 116 may be formed through the layers 109, 110, 111 using an appropriate cutting technique, for example laser etching and subsequently filled with metal or another appropriate conductive material. Distribution layers and solder pads may be formed on to the lower 109 and upper 111 layers prior to assembly of the device or after.

During manufacture the cavity 112, 115 may be filled with an inert gas and/or evacuated to provide a reduced-pressure atmosphere. Such atmospheres may improve the performance (by reducing resistance to movement) and lifetime (by controlling the atmosphere) of the MEMs component. An atmosphere with an appropriate amount of Oxygen may be utilised to facilitate anodic bonding of the layers. Other known packaging techniques may be utilised such as the incorporation of a “getter” in the cavity to trap materials out-gassed from the MEMs component.

The package 100 of FIG. 1 thus provides a packaged MEMs component for integration into systems, where the package includes electrical connection points for the MEMs component itself as well as providing redistribution and mounting functions. The MEMs component is packaged in an appropriate atmosphere for performance and lifetime considerations. The materials and bond processes are selected to provide an appropriately sealed cavity to retain any filling gas or reduced pressure over the lifetime of the device.

The manufacturing techniques utilised are adaptations of known and proven techniques, thereby providing a route by which MEMs devices can be packaged in commercial volumes and using commercially viable processes.

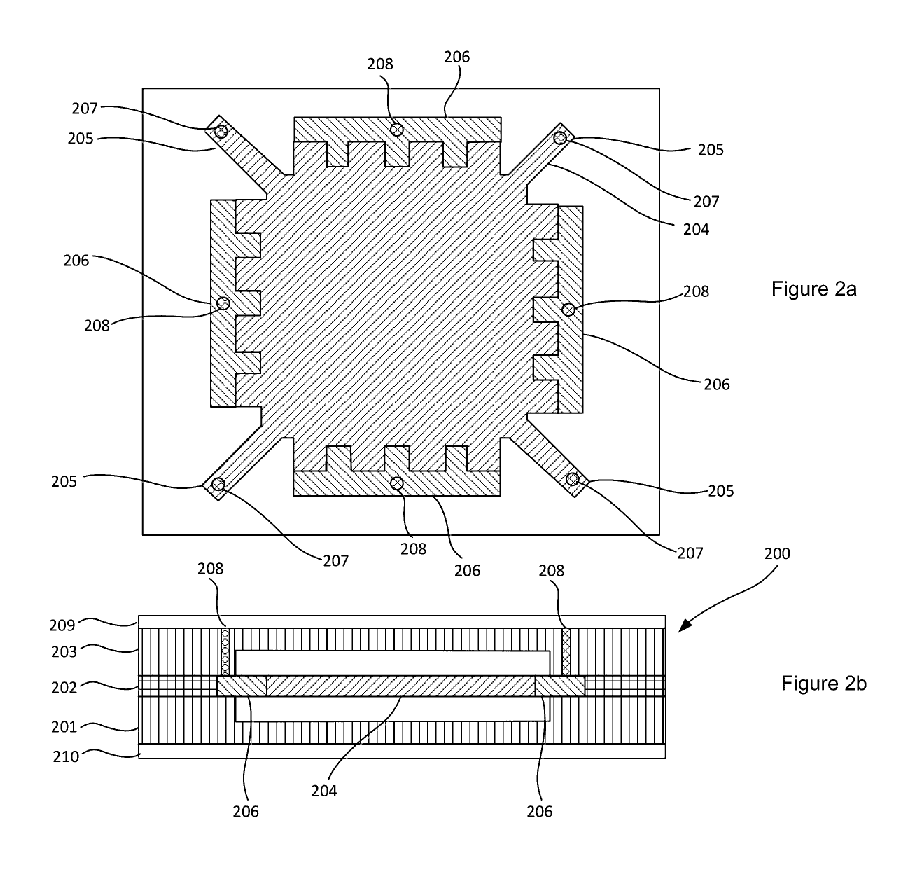

FIGS. 2a and 2b show cross-section and plan views of an alternative packaged MEMs device 200. The device of FIG. 2 utilises the triboelectric effect to generate an electrical signal. Packaging is accomplished using the same principles as described in relation to FIG. 1. Lower, spacer, and upper layers 201, 202, 203 are equivalent to the corresponding layers of the device of FIG. 1. In the FIG. 2 device the MEMs component 204 is a planar component bonded to the package at four corner locations 205. The MEMs component 204 is formed of a flexible material such that central region 206 can move up and down in the plane of FIG. 2a. Electrostatic components 206 are also bonded in the package and arranged such that the MEMs component 204 can move up and down in the plane of FIG. 2b relative to the electrostatic components 206.

Electrical connections are provided to the MEMs component 204 and electrostatic components 206 respectively utilising vias 207, 208 respectively through the upper or lower layers (vias are shown through upper layer 203 in the Figures, but the lower layer can also be utilised). Redistribution layers 209, 210 are provided on the upper and lower sides of the device as described in relation to FIG. 1.

In use the MEMs component moves up and down in the plane of FIG. 2b in response to movement of the device. Through friction between the MEMs component and the electrostatic components an electrical signal is generated between connections 207 and 208 due to the triboelectric effect. This signal can be used to power devices, for example by charging batteries. The MEMs and electrostatic components may be formed of any appropriate materials, for example, glass or acetate may be used for the electrostatic component and silicon for the MEMs component.

The MEMs components may be provided with a magnetic region on the movable parts, and magnetic regions may also be provided in the upper and lower layers in order to form a bistable device. Such devices may be capable of generating higher output levels under low excitation than conventional devices.

The terms upper, lower, up, and down have been used herein with reference to the orientation of the figures and thus apply to actual devices oriented according to those figures. It will be appreciated that this language does not restrict the scope of this disclose to devices only oriented in certain ways with respect to gravity.

In alternative examples, the spacer layer described hereinbefore may be omitted and the upper and lower layers may be shaped such that they are joined together to form the component. The layers are shaped such that the cavity is provided and the MEMs component is mounted between the layers.

Any range or device value given herein may be extended or altered without losing the effect sought, as will be apparent to the skilled person.

It will be understood that the benefits and advantages described above may relate to one embodiment or may relate to several embodiments. The embodiments are not limited to those that solve any or all of the stated problems or those that have any or all of the stated benefits and advantages.

Any reference to ‘an’ item refers to one or more of those items. The term ‘comprising’ is used herein to mean including the method blocks or elements identified, but that such blocks or elements do not comprise an exclusive list and a method or apparatus may contain additional blocks or elements.

The steps of the methods described herein may be carried out in any suitable order, or simultaneously where appropriate. Additionally, individual blocks may be deleted from any of the methods without departing from the spirit and scope of the subject matter described herein. Aspects of any of the examples described above may be combined with aspects of any of the other examples described to form further examples without losing the effect sought.

It will be understood that the above description of a preferred embodiment is given by way of example only and that various modifications may be made by those skilled in the art. Although various embodiments have been described above with a certain degree of particularity, or with reference to one or more individual embodiments, those skilled in the art could make numerous alterations to the disclosed embodiments without departing from the spirit or scope of this invention.

1. A packaged electronic component having at least one movable part, the packaged electronic component comprising:
lower and upper layers, each layer of the lower and upper layers formed with a depression in an inwards-facing side of the component, the depressions, forming a cavity within the packaged electronic component,
wherein each layer of the lower and upper layers includes a first layer formed with a through-hole in the depression and a second layer bonded over the through-hole such that the second layer and the depression form a single layer; and
a MEMs component rigidly joined at least at one proximal location to the lower and upper layers,
wherein the MEMs component extends from the at least one proximal location into the cavity such that a distal region of the MEMs component can move within the cavity.

2. A packaged electronic component according to claim 1, further comprising a spacer layer between the lower and upper layers.

3. A packaged electronic component according to claim 1, further comprising a redistribution layer on the outer face of the lower or upper layer.

4. A packaged electronic component according to claim 1, further comprising at least one electrical via connecting the MEMs component to at least one redistribution layer.

5. A packaged electronic component according to claim 1, further comprising a redistribution layer on the outer face of the lower and upper layers, and at least one electrical via between those redistribution layers.

6. A packaged electronic component according to claim 1, wherein the MEMs component is an elongate device rigidly joined at one location.

7. A packaged electronic component according to claim 1, wherein the MEMs component is a planar device rigidly joined at a plurality of locations.

8. A packaged electronic component according to claim 1, wherein the MEMs component acts as an energy harverster.

9. A packaged electronic component according to claim 1, wherein the MEMs component operates according to the triboelectric effect.

10. A packaged electronic component according to claim 1, further comprising magnetic material on the MEMs component to form a bistable device.

11. A packaged electronic component according to claim 2, wherein the upper and lower layers are formed of glass, and the spacer layer is formed of Silicon.

12. A packaged electronic component according to claim 2, wherein the MEMs component and spacer layer are formed of the same material.

13. A packaged electronic component according to claim 1, wherein the first layer is formed of glass and the second layer formed of Silicon.

14. A packaged electronic component according to claim 1, further comprising a getter in the cavity.

15. A packaged electronic component according to claim 1, wherein the cavity is filled with an inert gas.

16. A packaged electronic component according to claim 1, wherein the cavity is filled with a reduced pressure atmosphere.

17. A packaged electronic component according to claim 1, wherein the MEMs component provides an accelerometer function.

18. A packaged electronic component according to claim 1, wherein the MEMs component is formed of a flexible material.

19. A packaged electronic component according to claim 1, wherein the MEMs component includes piezo elements to convert the movement within the cavity to electricity.
